(19) United States
(12) Patent Application Publication
(10) Pub. No.: US 2006/0022291 A1
(43) Pub. Date: Feb. 2, 2006

(54) Unguarded schottky diodes with sidewall spacer at the perimeter of the diode

(76) Inventors: Vladimir Drobny, Tucson, AZ (US); Eric William Beach, Tucson, AZ (US); Derek William Robinson, Tucson, AZ (US)

Correspondence Address: TEXAS INSTRUMENTS INCORPORATED, P O BOX 655474, M/S 3999, DALLAS, TX, 75265, US

(21) Appl. No.: 10/901,003

(22) Filed: Jul. 28, 2004

(51) Int. Cl. H01L 27/095

(52) U.S. Cl. 257/471; 257/486

(57) ABSTRACT

An unguarded Schottky barrier diode structure, which may be part of an integrated device, is provided that blocks the formation of a parasitic MIS diode at the diode's perimeter. The diode is formed in a semiconductive material which may comprise silicon. The portion of the semiconductive material at which the diode is formed may be called a diode portion of the semiconductive material. A highly conductive buried layer is provided under the diode portion of the semiconductive material. The highly conductive buried layer may comprise TiW, Ti, or TiN. The highly conductive buried layer extends laterally to a conductive plug extending to an upper conductive layer of the integrated or other device. A laterally extended silicide region is provided, which extends laterally to a perimeter. The silicide region comprises a lower semiconductor contact area on top of and in contact with the semiconductive material. The lower semiconductor contact area extends laterally to the perimeter. An insulative barrier is provided which surrounds the perimeter of the silicide region. A side wall spacer is provided which extends from the lateral edge portion of the insulative barrier to cover and contact part of the perimeter, thereby physically blocking formation of a parasitic MIS diode at the perimeter. A conductive diffusion barrier layer covers at least portions of the insulative barrier, the side wall spacer, and the silicide region.

### CROSS REFERENCE TO RELATED APPLICATIONS

N/A

### STATEMENT REGARDING FEDERALLY SPONSORED RESEARCH OR DEVELOPMENT

N/A

### BACKGROUND OF THE INVENTION

The present invention is related to integrated circuits, and the formation of Schottky barrier diodes within such integrated circuits. Schottky barrier diodes (SBDs) are typically formed between a metal or near-noble metal silicide and an n-type silicon which provides a lower forward voltage drop than that of a standard p-n junction diode. An SBD is a majority carrier device offering much faster switching time than that of a minority carrier p-n junction diode.

An unguarded SBD (USBD) suffers from the formation of a parasitic, low barrier height perimeter MIS (metal insulator semiconductor) diode, in parallel with a higher barrier height near-noble metal silicide. This causes a current leakage and non-ideal IV characteristics. This unwanted MIS diode is formed by a lower barrier height TiW (titanium tungsten) or TiN (titanium nitride) metal/oxide/n-type silicon stack at the diode perimeter.

Guarded SBDs (GSBDs) eliminate the formation of this parasitic perimeter diode in the GSBD by providing a surrounding p-doped region which forms a p-n junction with the n-type silicon.

U.S. Pat. No. 4,622,736, is directed to a USBD device formed to block the parasitic MIS perimeter diode. The device includes a VSi₂ (vanadium silicide) layer. To block the formation of the parasitic MIS perimeter diode in such a device, a VSi₂ lip is formed, specifically at the perimeter of the silicide portion of the diode. This forms a lip which intersects the lateral edge portion of the insulative barrier that surrounds the diode, a portion of the conductive diffusion barrier layer covering the diode, and the perimeter of the silicide region.

### BRIEF SUMMARY OF THE INVENTION

An unguarded Schottky barrier diode structure, which may be part of an integrated device, is provided that blocks the formation of a parasitic MIS diode at the diode's perimeter. The diode is formed in a semiconductive material which may comprise silicon. The portion of the semiconductive material at which the diode is formed may be called a diode portion of the semiconductive material. A highly conductive buried layer is provided under the diode portion of the semiconductive material. The highly conductive buried layer may comprise TiW, Ti, or TiN. The highly conductive buried layer extends laterally to a conductive plug extending to an upper conductive layer of the integrated or other device.

A laterally extended silicide region is provided which extends laterally to a perimeter. The silicide region comprises a lower semiconductor contact area on top of and in contact with the semiconductive material. The lower semiconductor contact area extends laterally to the perimeter. The silicide region may comprise VSi₂ (vanadium silicide), Pd₂Si (palladium silicide), PtSi (platinum silicide), or NiSi (nickel silicide).

An insulative barrier is provided, which surrounds the perimeter. The insulative barrier is provided on top of and in contact with the semiconductive material. The insulative material may surround the perimeter and be adjacent to the perimeter. The insulative barrier which surrounds the perimeter may be in contact with the perimeter. The insulative barrier may comprise an insulative oxide, which may comprise silicon oxide. The insulative barrier comprises a lateral edge portion at or near the perimeter.

A sidewall spacer is provided which extends from the lateral edge portion of the insulative barrier to cover and contact part of the perimeter, thereby physically blocking formation of the parasitic MIS diode at the perimeter. The sidewall spacer may comprise a dielectric. More specifically, the sidewall spacer may comprise an insulative semiconductor material. By way of example, the sidewall spacer may comprise SiO₂ (silicon dioxide), Si₃N₄ (silicon nitride), or SiOₓN_{y} (silicon oxy-nitride).

A conductive diffusion barrier layer may be provided which covers a portion of the insulative barrier, the sidewall spacer, and the silicide region. The conductive diffusion barrier may comprise a diffusion barrier metal. For example, it may comprise TiW, Ti, or TiN.

Other features, functions, and aspects of the invention will be evident from the Detailed Description that follows.

### BRIEF DESCRIPTION OF THE SEVERAL VIEWS OF THE DRAWINGS

The invention will be more fully understood with reference to the following Detailed Description in conjunction with the drawings of which:

FIG. 1 is a cross-sectional side elevation view of portions of an unguarded Schottky barrier diode;

FIG. 2 is a cross-sectional side elevation view of portions of a Schottky barrier diode structure in accordance with the illustrated embodiment of the present invention; and

FIG. 3 is a cross-sectional side elevation view of portions of a Schottky barrier diode structure in accordance with the illustrated embodiment of the present invention.

### DETAILED DESCRIPTION OF THE INVENTION

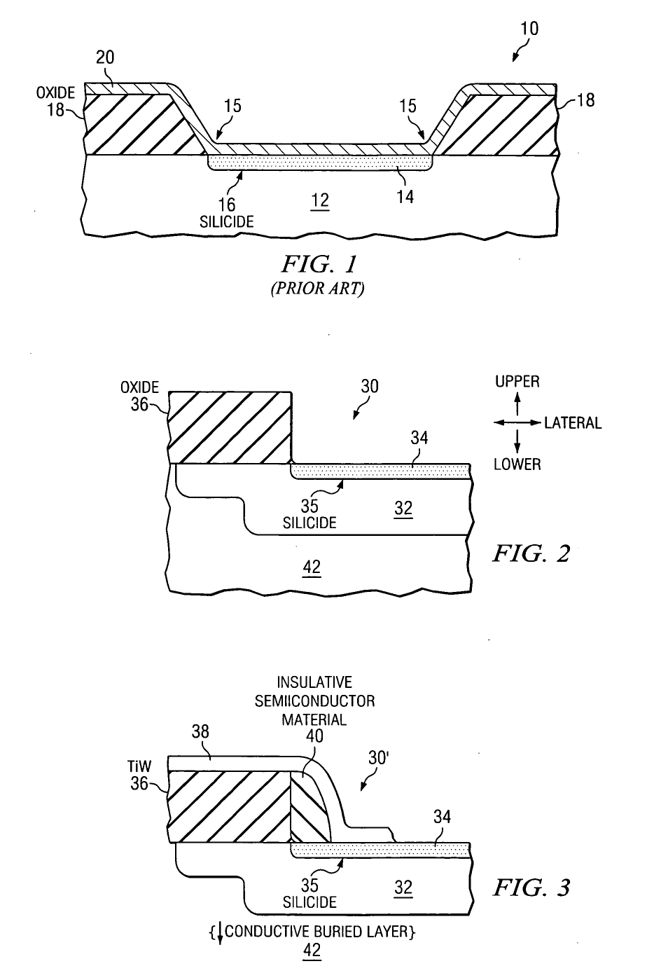

Referring now to the drawings in greater detail, FIG. 1 shows a conventional Schottky barrier diode structure. The illustrated structure 10 comprises a silicon substrate 12. A highly conductive buried layer (not shown) is provided under a diode portion of the silicon substrate 12. The highly conductive buried layer may extend laterally to a conductive plug (not shown) extending to an upper conductive layer of the integrated device of which the illustrated conventional SBD structure 10 forms a part. The illustrated structure further comprises a laterally extended silicide region 14. The illustrated silicon substrate comprises an n-type silicon. The silicide region extends laterally to a perimeter 15, surrounding silicide region 14. Silicide region 14 further comprises a lower semiconductor contact area 16 on top of and in contact with semiconductor substrate 12. The lower semiconductor contact area 16 extends laterally to perimeter 15 of silicide region 14.

An insulative barrier 18 is provided which comprises an oxide material 18 and surrounds perimeter 15 of silicide region 14. The illustrated insulative barrier 18 comprises a lateral edge portion at perimeter 15 of the silicide region 14. A conductive diffusion barrier layer 20 covers portions of the insulative barrier and silicide region 14. In the illustrated structure 10, diffusion barrier layer 20 comprises TiW. Other examples of diffusion barrier metals include Ti and TiN.

To facilitate describing the concepts herein, certain conventions are used to indicate the positioning and direction of various features of the illustrated structures. The conventions are illustrated in the upper right hand portion of the box of FIG. 2. It is not necessary that the illustrated structures be positioned as shown in the figures. For example, they could be positioned on their side or upside down, in which case the normal meanings of the terms upper, lower, and lateral would not apply. Since the illustrated structures are described with reference to these figures, and oriented as such, the upper direction is your typical upper direction as shown by the upper arrow in FIG. 2, lateral directions correspond to the normal meaning of the term as shown by the lateral arrows in FIG. 2, and the lower direction is as shown with the corresponding arrow in FIG. 2.

FIG. 2 shows portions of a preliminary stage of a Schottky barrier diode structure in accordance with the illustrated embodiment of the present invention. A preliminary stage structure 30 is shown which comprises a semiconductive material substrate 32, which comprises an n-type silicon substrate in the illustrated embodiment. A laterally extended silicide region 34 is provided which comprises a lower semiconductor contact area 35 on top of and in contact with a diode portion of the illustrated semiconductive material substrate 32. The lower semiconductor contact area 35 of the silicide region 34 extends laterally to the perimeter of silicide region 34. An insulative barrier 36 is provided, which in the illustrated embodiment comprises silicon oxide. The insulative barrier 36 is provided on top of and in contact with portions of semiconductive material substrate 32, and surrounds the perimeter of silicide region 34. The insulative barrier may be adjacent to the perimeter of silicide region 34 and in contact with the perimeter of silicide region 34, and comprises a lateral edge portion at or near the perimeter.

The silicide region may be formed within a silicon wafer using well-known processes which include placing a photoresist at areas to be protected, and using a chemical etch to create an empty region for formation of silicide region 34. The silicide layer is formed in the empty region, and, thereafter, the oxide layer 36 is formed using an appropriate deposition process.

Before formation of the conductive diffusion barrier layer 38, in the structure shown in FIG. 3, a side wall spacer 40 is formed. In the illustrated embodiment, side wall spacer 40 comprises a dielectric side wall spacer which extends from the lateral edge portion of insulative barrier 36 to cover and contact part of the perimeter of silicide region 34, thereby physically blocking formation of an unwanted parasitic MIS diode at the perimeter. By way of example, known processes may be used to form the side wall spacer, including depositing of an oxide or nitride, and etching the deposited formation with reactive ions. The side wall spacer may comprise an insulative semiconductor material such as SiO₂ (silicon dioxide), Si₃N₄ (silicon nitride), or SiOₓN_{y} (silicon oxy-nitride).

A highly conductive buried layer 42 is provided under the diode portion of the semiconductive material substrate 32. The highly conductive buried layer may comprise TiW, Ti or TiN. The buried layer extends laterally to a conductive plug (not shown) extending to an upper conductive layer of the resulting integrated or other device.

The structure shown in FIG. 3 may be manufactured using any metal silicide, including the near-noble metal silicide group of metals. USBD devices formed by near-noble metal silicides are sensitive to the current leakage effects caused by the formation of a low barrier parasitic MIS diode which is avoided on the illustrated embodiment. Near-noble metal silicides offer higher barrier heights than metals from the transition refractory metal group.

It should be appreciated that modifications to and variations of the above-described structures may be made without departing from the concepts disclosed herein. Accordingly, the invention should not be viewed as limited except as by the scope and spirit of the appended claims.

What is claimed is:

1. A Schottky barrier diode structure comprising:
a diode portion of a semiconductive material substrate;
a highly conductive buried layer under the diode portion of the semiconductive material;
a laterally extended silicide region extending laterally to a perimeter, the silicide region comprising a lower semiconductor contact area on top of and in contact with the semiconductive material, the lower semiconductor contact area extending laterally to the perimeter;
an insulative barrier surrounding the perimeter, the insulative barrier comprising a lateral edge portion at or near the perimeter; and
a side wall spacer extending from the lateral edge portion of the insulative barrier to cover and contact part of the perimeter, thereby physically blocking the formation of a parasitic MIS diode at the perimeter.

2. The structure according to claim 1, wherein the semiconductive material comprises silicon.

3. The structure according to claim 2, wherein the semiconductive material substrate comprises n-type silicon.

4. The structure according to claim 1, wherein the highly conductive buried layer comprises TiW.

5. The structure according to claim 1, wherein the highly conductive buried layer comprises Ti.

6. The structure according to claim 1, wherein the highly conductive buried layer comprises TiN.

7. The structure according to claim 1, wherein the highly conductive buried layer extends laterally to a conductive plug extending to an upper conductive layer of an integrated device.

8. The structure according to claim 1, wherein the silicide region comprises VSi₂.

9. The structure according to claim 1, wherein the silicide region comprises Pd₂Si.

10. The structure according to claim 1, wherein the silicide region comprises PtSi.

11. The structure according to claim 1, wherein the silicide region comprises NiSi.

12. The structure according to claim 1, wherein the insulative barrier is on top of and in contact with the semiconductive material.

13. The structure according to claim 12, wherein the insulative barrier surrounds the perimeter and is adjacent to the perimeter.

14. The structure according to claim 12, wherein the insulative barrier surrounds the perimeter and is in contact with the perimeter.

15. The structure according to claim 1, wherein the insulative barrier comprises an insulative oxide.

16. The structure of claim 15, wherein the insulative oxide comprises silicon oxide.

17. The structure according to claim 1, wherein the side wall spacer comprises a dielectric material.

18. The structure according to claim 1, wherein the side wall spacer comprises an insulative semiconductive material.

19. The structure according to claim 18, wherein the side wall spacer comprises silicon dioxide.

20. The structure according to claim 18, wherein the side wall spacer comprises silicon nitride.

21. The structure according to claim 18, wherein the side wall spacer comprises silicon oxy-nitride.

22. The structure according to claim 1, further comprising a conductive diffusion barrier layer covering at least portions of the insulative barrier, the side wall spacer, and the silicide region.

23. The structure according to claim 22, wherein the conductive diffusion barrier layer comprises TiW.

24. The structure according to claim 22, wherein the conductive diffusion barrier layer comprises Ti.

25. The structure according to claim 22, wherein the conductive diffusion barrier layer comprises TiN.

26. An integrated device having a semiconductive material substrate, the device comprising:
a diode portion of a semiconductive material substrate;
a highly conductive buried layer under the diode portion of the semiconductive material;
a laterally extended silicide region extending laterally to a perimeter, the silicide region comprising a lower semiconductor contact area on top of and in contact with the semiconductive material, the lower semiconductor contact area extending laterally to the perimeter;
an insulative barrier surrounding the perimeter, the insulative barrier comprising a lateral edge portion edge at or near the perimeter; and
a side wall spacer extending from the lateral edge portion of the insulative barrier to cover and contact part of the perimeter, thereby physically blocking the formation of a parasitic MIS diode at the perimeter.

27. The integrated device according to claim 26, wherein the semiconductive material substrate comprises silicon.

28. The integrated device according to claim 27, wherein the semiconductive material substrate comprises n-type silicon.
